(19) United States
(12) Patent Application Publication
(10) Pub. No.: US 2001/0045646 A1
(43) Pub. Date: Nov. 29, 2001

(54) SILICON OXYNITRIDE ARC FOR METAL PATTERNING

(76) Inventors: JEFFREY A. SHIELDS, SUNNYVALE, CA (US); KING WAI KELWIN KO, SAN JOSE, CA (US); ANNE E. SANDERFER, CAMPBELL, CA (US); PAUL A. BESSER, AUSTIN, TX (US)

Correspondence Address: MCDERMOTT WILL & EMERY, 600 13TH STREET, N.W., WASHINGTON, DC, 20005-3096, US

(21) Appl. No.: 09/371,920

(22) Filed: Aug. 11, 1999

(51) Int. Cl. H01L 23/52

(52) U.S. Cl. 257/734

(57) ABSTRACT

A SiON ARC/hard mask is formed on a metal layer and patterned, thereby avoiding a separate hard mask. The use of SiON as a combined ARC/hard mask enables a reduction in the height of the metal stack, thereby reducing capacitance between metal lines and increasing circuit speed. In addition, etch marginality is improved due to the reduced aspect ratio. Embodiments include forming a thin silicon oxide layer on the SiON arc/hard mask before depositing a deep UV photoresist layer to minimize footing.

### TECHNICAL FIELD

The present invention relates to a method of manufacturing a semiconductor device having sub-micron features. The present invention has particular applicability in manufacturing semiconductor devices with a design rule of about 0.18 micron and under with accurately dimensioned conductive features.

### BACKGROUND ART

The escalating requirements for high density and performance associated with ultra-large scale integration require responsive changes in electrical interconnect patterns, which is considered one of the most demanding aspects of ultra-large scale integration technology. Demands for ultra-large scale integration semiconductor wiring require increasingly denser arrays with minimal spacing between conductive lines. Implementation becomes problematic in manufacturing semiconductor devices having a design rule of about 0.18 micron and under, e.g., about 0.15 micron and under.

Semiconductor devices typically comprise a substrate and elements, such as transistors and/or memory cells, thereon. Various interconnection layers are formed on the semiconductor substrate to electrically connect these elements to each other and to external circuits. The formation of interconnection layers is partly accomplished utilizing conventional photolithographic techniques to form a photoresist mask comprising a pattern and transferring the pattern to an underlying layer or composite by etching the exposed underlying regions.

In accordance with conventional practices, interconnect structures comprise electrically conductive layers such as aluminum (Al), copper (Cu) or alloys thereof. In patterning the interconnect structure, an anti-reflective coating (ARC) is typically provided between the photoresist and the conductive layer to avoid deleterious reflections from the underlying conductive layer during patterning of the photoresist. For example, the ARC can reduce the reflectivity of an Al metal layer to 25-30% from a reflectivity of about 80-90%. ARCs are chosen for their optical properties and compatibility with the underlying conductive layer. However, many of the desirable ARCs, such as titanium nitride (TiN) contain basic components, such as nitrogen, which adversely interact with the photoresist material thereon during photolithographic processing, particularly in conventional deep-ultraviolet (deep-UV) resist processing, e.g., deep-UV radiation having a wavelength of about 100 nm to about 300 nm.

A conventional interconnect structure is illustrated in FIG. 1 and comprises substrate 8 with dielectric layer 10 thereon. A conductive layer 12 is formed on dielectric layer 10 and ARC 14 is formed on conductive layer 12. A photoresist layer 16, is formed on ARC 14. In very large scale integrated circuit applications, dielectric 10 has several thousand openings which can be either vias or lateral metallization lines where the metallization pattern serves to interconnect structures on or in the semiconductor substrate. Dielectric layer 10 can comprise inorganic layers such as silicon dioxide, silicon nitride, silicon oxynitride, etc. or organic layers such as polyimide or combinations of both. Conductive layer 12 typically comprises a metal layer such as Al, Cu, or alloys thereof. ARC 14 typically comprises a nitride of silicon or a nitride of a metal such as titanium, e.g., titanium nitride (TiN).

To achieve high density line wiring, photoresist coating 16 is typically a deep UV radiation sensitive photoresist capable of achieving line width resolutions of about 0.15 micron. During photolithographic processing, radiation is passed through mask 18 defining a desired conductive pattern to imagewise expose photoresist coating 16. After exposure to radiation, the photoresist layer is developed to form a relief pattern therein. It has been observed, however, that a residue remains at the photoresist interface and ARC, near the developed photoresist sidewall, resulting in a parabolic appearance, 22a and 22b, at the base of the photoresist known as “footing”, as shown in FIG. 2 wherein elements similar to those in FIG. 1 are denoted by similar reference numerals. In FIG. 2, reference numeral 20 denotes the photoresist mask. The footing problem is typical of conventional photolithographic techniques employing a photoresist coating over an ARC in forming interconnections. Footing of the photoresist during patterning results in a loss of critical dimensional control in the subsequently patterned underlying conductive layer limiting the ability to resolve small spaces between conductive lines and thus limiting wiring density.

The conventional approach to the footing problem illustrated in FIG. 2 comprises the formation of a hard mask, such as silicon oxide derived from tetraethyl orthsilicate (TEOS) on the TiN ARC layer to prevent interaction of a basic component, e.g., nitrogen, in the ARC with the deep UV photoresist mask. The metal stack, however, is quite high and presents an unfavorable aspect ratio leading to an undesirably high capacitance between the metal lines and a poor etch margin. For example, a conventional metal stack comprises a lower barrier metal layer of titanium, TiN, titanium tungsten or titanium/tin at a thickness of about 250 Å to about 750 Å. Al or an Al alloy deposited thereon typically has a thickness of about 4,000 Å to about 8,000 Å. The typical TiN or Ti/TiN ARC layer has a thickness of about 750 Å to about 1,150 Å, while the hard mask typically has a thickness of at least 300 Å. Thus, the typical combined thickness of the hard mask and ARC layer is about 1,500 Å.

In copending U.S. application Ser. No. 09/163,601 filed on Sep. 30, 1998, it was reported that certain oxide films themselves contain nitrogen or other components which adversely interact with deep UV photoresist materials as, for example, nitrogen or nitrogen products stemming from the use of silane and nitrite oxide. The invention disclosed in copending U.S. application Ser. No. 09/163,601 comprises depositing an oxide layer on a TiN ARC by plasma enhanced chemical vapor deposition (PECVD) from an organosilicon compound, such as an alkoxysilane, e.g., TEOS, or by high density plasma (HDP) oxide deposition of a silicon oxide film. Such oxide films are free of adverse interactions with a photoresist coating thereon.

In U.S. Pat. No. 5,837,576 a silicon oxide nitride etching stop layer is employed to pattern a storage node of a capacitor.

There exists a need for methodology enabling patterning of a metal line, particular with deep UV photoresist techniques, reduced interwiring capacitance and improved etch marginality. There exists a further need for such methodology to achieve improved line width accuracy with minimal interwiring spacings.

### SUMMARY OF THE INVENTION

An advantage of the present invention is a semiconductor device having accurately dimensioned conductive features.

Another advantage of the present invention is the use of a thinner metal stack for patterning metal lines, thereby decreasing interwirng capacitance and improving etch marginality.

Another advantage of the present invention is a method of accurately patterning a metal line employing a reduced amount of photoresist thereby enhancing photolithographic capabilities.

An additional advantage of the present invention resides in reducing the via resistance by employing a removable silicon oxynitride ARC/hard mask.

Additional advantages and features of the present invention will be set forth in part in the description which follows and in part will become apparent to those having ordinary skill in the art upon examination of the following or may be learned from the practice of the invention. The advantages of the present invention may be realized and obtained as particularly pointed out in the appended claims.

According to the present invention, the foregoing and other advantages are achieved in part by a method of manufacturing a semiconductor device, the method comprising forming a metal layer over a substrate; forming a silicon oxynitride layer on the metal layer; forming a photoresist pattern on the silicon oxynitride layer; and etching to pattern the metal layer, wherein the silicon oxynitride layer serves as an anti-reflective coating and a hard mask.

Another aspect of the present invention is a semiconductor device comprising a metal layer; a silicon oxynitride layer on a metal layer; and a thin oxide layer on the silicon oxynitride layer.

Embodiments of the present invention comprise utilizing a silicon oxynitride (SiON) layer as a combined ARC and hard mask having a thickness of about 300 Å to about 700 Å, e.g., about 500 Å. Embodiments of the present invention further comprise reducing photoresist footings by forming a thin silicon oxide layer, having a thickness of about 20 Å to about 300 Å, on the SiON ARC/hard mask, as by PECVD deposition from TEOS or by depositing a HDP oxide.

Additional advantages of the present invention will become readily apparent to those skilled in this art from the following detailed description, wherein only the preferred embodiment of the present invention is shown and described, simply by way of illustration of the best mode contemplated for carrying out the present invention. As will be realized, the invention is capable of other and different embodiments, and its several details are capable of modifications in various obvious respects, all without departing from the present invention. Accordingly, the drawing and description are to be regarded as illustrative in nature, and not as restrictive.

### BRIEF DESCRIPTION OF THE DRAWINGS

FIG. 1 schematically depicts a conventional interconnect structure prior to radiation exposure.

FIG. 2 schematically illustrates a conventional interconnect structure having a patterned photoresist line.

FIG. 3 schematically illustrates an embodiment of the present invention.

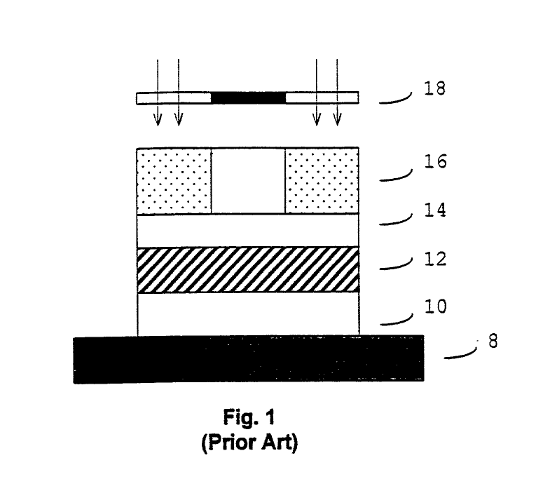

### DESCRIPTION OF THE INVENTION

The present invention stems from the discovery that a relatively thin SiON layer, such as about 300 Å to about 700 Å, e.g., about 500 Å, can advantageously and effectively replace both a conventional hard mask, typically Ti, TiN, or Ti/TiN ARC, and an oxide hard mask which typically has a combined total of about 1,500 Å. The reduction in the height of the metal stack advantageously reduces the capacitance between the metal lines which, in turn, leads to higher circuit speed. In addition, the reduction of the metal stack thickness improves metal etch marginality by virtue of reducing the aspect ratio. A further advantage of the present invention is that the SiON is deposited at a thickness greater than that at which a separate oxide hard mask would be employed and still produce a thinner gate stack thereby increasing the benefit of the hard mask. As a result, the resist can be reduced in thickness, e.g., down to about 7,000 Å to about 9,000 Å, thereby improving photolithographic capability as well. In accordance with embodiments of the present invention, the SiON ARC/hard mask can, if desired, be removed after metal etching in the resist stripper or in a different etch chamber employing fluorine chemistry at elevated temperatures, e.g., about 100° C. to about 240° C.

Advantageously, the use of a SiON ARC/hard mask performs the traditional functions of an ARC for photolithographic needs as well as serving as an etch stop layer. In addition, the use of an SiON prevents the attack of the metal lines for very thin resist layers. Embodiments of the present invention comprise further improvements in footing by treating the surface of the deposited SiON layer to form a thin oxide coating thereon, e.g., an oxide coating having a thickness of about 20 Å to about 300 Å. This can be accomplished by treating the SiON surface with a plasma containing O2/N2 or N20 to generate a thin oxide layer of 20 to 50 Å thickness. The N20 plasma can efficiently be conducted in-situ after the SiOn deposition. Alternately, a thin layer of silicon oxide layer can be deposited by PECVD employing TEOS or by HDP oxide deposition.

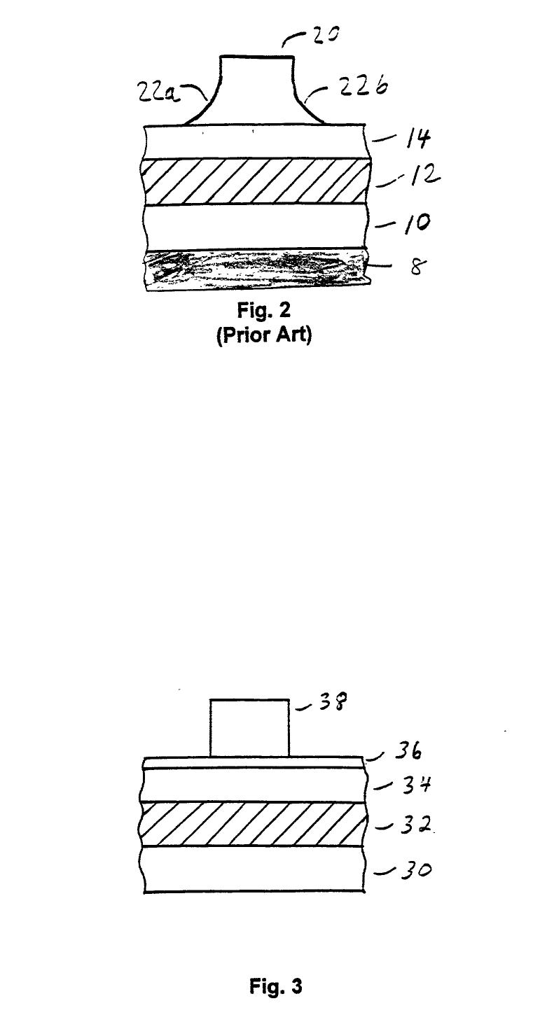

An embodiment of the present invention is schematically illustrated in FIG. 3 and comprises dielectric layer 30 and conductive layer 32 formed over dielectric layer 30. Conductive layer 32 can comprise a conventional composite of a first barrier metal layer, such as Ti, TiN, TiW or Ti/TiN, at a thickness of about 250 Å to about 750 Å and an Al or Al alloy layer thereon at a thickness of about 4,00 Å to about 8,000 Å. A SiON ARC/hard mask 34 is deposited on the upper surface of conductive layer 32 at a thickness of about 300 Å to about 700 Å, e.g., about 500 Å. SiON ARC/hard mask can be deposited in a conventional manner, such as PECVD employing monosilane, nitrous oxide (N₂O) and ammonia. The reactants are adjusted consistent with conventional practices to optimize the refractive index of the deposited SiON layer to function effectively as an ARC. The photoresist mask 38 typically comprises a material sensitive to deep UV radiation and is formed on the SiON ARC/hard mask 34. The surface of the SiON ARC/hard mask is advantageously modified by providing a thin oxide layer 36 for improved resistance to footing. Silicon oxide layer 36 can be formed at a thickness of about 20 Å to about 300 Å without significantly increasing the height of the stack. Advantageously, since SiON layer 34 also serves as a hard mask, the thickness of the photoresist mask 38 can be reduced to about 7,000 Å to about 9,000 Å. Silicon oxide layer 36 can be formed by the methodology disclosed in copending application Ser. No. 09/163,601 filed on Sep. 30, 1998, the entire disclosure of which is hereby incorporated by reference herein.

The present invention enjoys industrial utility in manufacturing any of various types of semiconductor devices, particularly semiconductor devices having features in the deep sub-micron range, such as about 0.18 micron and under, e.g., about 0.15 micron and under. The present invention advantageously enables manufacturing semiconductor devices employing deep UV photoresist technology without encountering significant footing and with reduced interwiring capacitance, thereby increasing circuit speed. In addition, the methodology of the present invention enjoys superior etch marginality due to a reduced aspect ratio stemming from reducing the metal stack for patterning and enables the use of a thinner resist thereby enhancing photolithographic flexibility.

Only the preferred embodiment of the present invention and an example of its versatility is shown and described in the present disclosure. It is to be understood that the present invention is capable of use in various other combinations and environments and is capable of changes or modifications within the scope of the inventive concept as expressed herein.

What is claimed is:

1. A method of manufacturing a semiconductor device, the method comprising:
forming a metal layer over a substrate;
forming a silicon oxynitride layer on the metal layer;
forming a photoresist pattern on the, silicon oxynitride layer; and
etching to pattern the metal layer, wherein the silicon oxynitride layer serves as an anti-reflective coating and a hard mask.

2. The method according to claim 1, further comprising forming a thin oxide layer on the silicon oxynitride layer.

3. The method according to claim 2, comprising forming a silicon oxide layer as the oxide layer.

4. The method according to claim 3, further comprising removing the oxide layer and silicon oxynitride layer after etching.

5. The method according to claim 3, comprising forming the silicon oxynitride layer at a thickness of about 300 Å to about 700 Å.

6. The method according to claim 5, comprising forming the silicon oxide layer at a thickness of about 20 Å to about 300 Å.

7. The method according to claim 1, further comprising forming a barrier layer and forming the metal layer on the barrier layer.

8. The method according to claim 1, wherein the photoresist pattern comprises a deep UV photoresist material.

9. The method according to claim 4, comprising:
etching to pattern the metal layer to form a plurality of metal lines separated by interwiring spacings; and
depositing a dielectric layer to gap fill the interwiring spacings.

10. The method according to claim 9, further comprising:
depositing a dielectric layer over the gap filled patterned metal layer; and
planarizing by chemical-mechanical polishing.

11. A semiconductor device comprising:
a metal layer;
a silicon oxynitride layer on a metal layer, and
a thin oxide layer on the silicon oxynitride layer.

12. The semiconductor device according to claim 9, wherein the oxide layer comprises a silicon oxide.

13. The semiconductor device according to claim 10, wherein the silicon oxynitride layer has a thickness of about 300 Å to about 700 Å.

14. The semiconductor device according to claim 11, wherein the silicon oxide layer has a thickness of about 20 Å to about 300 Å.
